(19) United States
(12) Patent Application Publication
(10) Pub. No.: US 2025/0185479 A1
(43) Pub. Date: Jun. 5, 2025

(54) DISPLAY SUBSTRATE, MANUFACTURING METHOD THEREFOR, AND DISPLAY APPARATUS

(71) Applicants: Hefei Xinsheng Optoelectronics Technology Co., Ltd., Hefei, Anhui (CN); BOE Technology Group Co., Ltd., Beijing (CN)

(72) Inventors: Ning LIU, Beijing (CN); Liangchen YAN, Beijing (CN); Bin ZHOU, Beijing (CN); Haitao WANG, Beijing (CN); Jiawen SONG, Beijing (CN); Biao WANG, Beijing (CN)

(21) Appl. No.: 18/862,014

(22) PCT Filed: Jan. 2, 2024
(86) PCT No.: PCT/CN2024/070044

§ 371 Date: Oct. 31, 2024

(30) Foreign Application Priority Data
Jan. 30, 2023 (CN) 202310107698.6

(51) Int. Cl. H10K 59/131; H10K 59/12; H10K 71/60; H10K 102/00

(52) U.S. Cl. CPC H10K 59/131; H10K 59/1201; H10K 71/60; H10K 2102/351

(57) ABSTRACT

The present application provides a display substrate, a manufacturing method therefor, and a display apparatus. The display substrate includes a substrate, a plurality of sub-pixels located on the substrate, an auxiliary electrode located on the substrate, and an isolation structure located at a side of the auxiliary electrode away from the substrate. The sub-pixels each include a first electrode, a light-emitting material layer, and a second electrode. The isolation structure includes a first conductive portion, a second conductive portion located at a side of the first conductive part away from the substrate, and a third conductive portion located at a side of the second conductive portion away from the substrate.

### CROSS REFERENCE TO RELATED APPLICATIONS

The present application is a U.S. National Stage of International Application No. PCT/CN2024/070044 filed on Jan. 2, 2024 which claims the priority benefit of Chinese Patent Application No. 2023101076986 filed on Jan. 30, 2023, and the content of which is incorporated herein by reference in its entirety.

### TECHNICAL FIELD

The present disclosure relates to the field of display technologies and in particular to a display substrate and a manufacturing method therefor and a display apparatus.

### BACKGROUND

For top-emitting display panels, in order to increase emission rate of light emitted by sub-pixels, thickness of a cathode of the sub-pixels is usually set to small. But the small cathode thickness can lead to a large resistance and large voltage drop of the cathode. As a result, a significant difference in current between the sub-pixels in a central region and an edge region of the display panel is generated, causing non-uniform display brightness of the display panel and bringing poor use experience to users.

### SUMMARY

The present disclosure provides a display substrate and a manufacturing method therefor and a display apparatus.

According to a first aspect of embodiments of the present disclosure, there is provided a display substrate. The display substrate includes:
a substrate;
a plurality of sub-pixels located at a side of the substrate, where the plurality of sub-pixels are located in a display region; the sub-pixel includes a first electrode, a light-emitting material layer at a side of the first electrode away from the substrate, and a second electrode at a side of the light-emitting material layer away from the substrate;
an auxiliary electrode located at a side of the substrate;
an isolation structure at a side of the auxiliary electrode away from the substrate; where the isolation structure includes a first conductive portion, a second conductive portion at a side of the first conductive portion away from the substrate, and a third conductive portion at a side of the second conductive portion away from the substrate; an orthographic projection of the second conductive portion on the substrate falls within an orthographic projection of the third conductive portion on the substrate, and an area of the orthographic projection of the second conductive portion on the substrate is less than an area of the orthographic projection of the third conductive portion on the substrate; the isolation structure is electrically connected with the auxiliary electrode; a thickness of a part of the third conductive portion beyond the second conductive portion is less than a thickness of a part of the third conductive portion in contact with the second conductive portion; the isolation structure is electrically connected with the second electrode.

In some embodiments, the thickness of the part of the third conductive portion in contact with the second conductive portion is greater than a thickness of the first conductive portion.

In some embodiments, a ratio of the thickness of the part of the third conductive portion in contact with the second conductive portion to the thickness of the first conductive portion ranges from 2 to 5.

In some embodiments, the orthographic projection of the third conductive portion on the substrate falls within an orthographic projection of the first conductive portion on the substrate; the display substrate includes an electrode layer, and the electrode layer includes the second electrode of each sub-pixel; the electrode layer includes a plurality of electrode blocks, and each of the electrode blocks includes the second electrodes of one or more sub-pixels; adjacent electrode blocks are respectively lap-jointed with the same isolation structure.

In some embodiments, the first electrode includes a fourth conductive portion, a fifth conductive portion at a side of the fourth conductive portion away from the substrate, and a sixth conductive portion at a side of the fifth conductive portion away from the substrate; the fourth conductive portion and the first conductive portion are disposed in a same layer, the fifth conductive portion and the second conductive portion are disposed in a same layer, and the sixth conductive portion and the third conductive portion are disposed in a same layer.

In some embodiments, the first electrode further includes a seventh conductive portion at a side of the fourth conductive portion facing toward the substrate, and the isolation structure further includes an eighth conductive portion at a side of the first conductive portion facing toward the substrate; the seventh conductive portion and the eighth conductive portion are disposed in a same layer.

In some embodiments, the display substrate further includes a pixel circuit layer between the substrate and the sub-pixels; the pixel circuit layer includes a plurality of conductive structures; the auxiliary electrode and at least one of the conductive structures are disposed in a same layer.

In some embodiments, the display region includes a light-emitting region and a light-transmitting region between adjacent light-emitting regions; the sub-pixels are located in the light-emitting region; the isolation structure is located in the light-transmitting region; the display substrate further includes a pixel circuit layer between the substrate and the sub-pixels, and the pixel circuit layer includes at least one organic layer;
an orthographic projection of the isolation structure on the substrate is not overlapped with an orthographic projection of the at least one organic layer on the substrate.

In some embodiments, the display region includes a light-emitting region and a light-transmitting region between adjacent light-emitting regions; the sub-pixels are located in the light-emitting region; the isolation structure is located in the light-transmitting region; the display substrate further includes a pixel circuit layer between the substrate and the sub-pixels, and the pixel circuit layer includes at least one organic layer;
the isolation structure includes a first-class isolation structure and a second-class isolation structure, and a distance of the first-class isolation structure from the first electrode is less than a distance of the second-class isolation structure from the first electrode; an orthographic projection of the first-class isolation structure on the substrate is overlapped with an orthographic projection of the at least one organic layer on the substrate, and an orthographic projection of the second-class isolation structure on the substrate is not overlapped with the orthographic projection of the at least one organic layer on the substrate.

In some embodiments, the at least one organic layer includes an organic material layer, and the first-class isolation structure includes a first portion, a second portion and a third portion sequentially connected; the first portion is located at a side of the organic material layer away from the substrate, the second portion is located at a side part of the organic material layer, and an orthographic projection of the third portion on the substrate is not overlapped with an orthographic projection of the organic material layer on the substrate.

In some embodiments, the first conductive portion has the same material as the third conductive portion.

In some embodiments, a thickness difference between the part of the third conductive portion in contact with the second conductive portion and the part of the third conductive portion beyond the second conductive portion is d1, a length of the third conductive portion beyond the second conductive portion is d2, and a ratio of d2 to d1 ranges from 10 to 40.

In some embodiments, a side surface of the second conductive portion is an inclined surface and an included angle between the inclined surface and a surface of the substrate ranges from 30° to 80°.

According to a second aspect of embodiments of the present disclosure, there is provided a manufacturing method of a display substrate. The display substrate includes a plurality of sub-pixels in a display region, the sub-pixel includes a first electrode, a second electrode, and a light-emitting material layer between the first electrode and the second electrode. The manufacturing method includes:
providing a substrate, where the second electrode is located at a side of the first electrode away from the substrate;
forming an auxiliary electrode on the substrate;
forming a conductive film layer at a side of the auxiliary electrode away from the substrate, where the conductive film layer includes a first conductive layer, a second conductive layer at a side of the first conductive layer away from the substrate, and a third conductive layer at a side of the second conductive layer away from the substrate; a thickness of the first conductive layer is less than a thickness of the third conductive layer;
etching the third conductive layer to obtain a third conductive portion;
etching the second conductive layer to obtain a second conductive portion, wherein the orthographic projection of the second conductive portion on the substrate falls within the orthographic projection of the third conductive portion on the substrate, and an area of the orthographic projection of the second conductive portion on the substrate is less than an area of the orthographic projection of the third conductive portion on the substrate;
etching the first conductive layer by using an etching solution to obtain a first conductive portion; where at the same time, the etching solution etches a surface, facing toward the substrate, of the part of the third conductive portion beyond the second conductive portion such that the thickness of the part of the third conductive portion beyond the second conductive portion is reduced so as to obtain an isolation structure including the first conductive portion, the second conductive portion and the third conductive portion; the isolation structure is electrically connected with the auxiliary electrode;
forming the second electrode, where the second electrode is in contact with the isolation structure.

According to a third aspect of embodiments of the present disclosure, there is provided a display apparatus. The display apparatus includes:
a substrate;
a plurality of sub-pixels located at a side of the substrate, where the plurality of sub-pixels are located in a display region; the sub-pixel includes a first electrode, a light-emitting material layer at a side of the first electrode away from the substrate, and a second electrode at a side of the light-emitting material layer away from the substrate;
an auxiliary electrode located at a side of the substrate;
an isolation structure at a side of the auxiliary electrode away from the substrate: where the isolation structure includes a first conductive portion, a second conductive portion at a side of the first conductive portion away from the substrate, and a third conductive portion at a side of the second conductive portion away from the substrate: an orthographic projection of the second conductive portion on the substrate falls within an orthographic projection of the third conductive portion on the substrate, and an area of the orthographic projection of the second conductive portion on the substrate is less than an area of the orthographic projection of the third conductive portion on the substrate: the isolation structure is electrically connected with the auxiliary electrode: a thickness of a part of the third conductive portion beyond the second conductive portion is less than a thickness of a part of the third conductive portion in contact with the second conductive portion: the isolation structure is electrically connected with the second electrode.

In the display substrate and the manufacturing method therefor and the display apparatus provided by the embodiments of the present disclosure, since the third conductive portion of the isolation structure goes beyond the second conductive portion, the light-emitting material layer of the sub-pixels can be broken at the sidewall of the isolation structure so as to enable the second electrode to be in contact with the isolation structure: the second electrode is electrically connected to the auxiliary electrode via the isolation structure such that the second electrode has a reduced resistance and a reduced voltage drop, reducing a current difference of the sub-pixels in a central region and an edge region of the display panel and improving the uniformity of the display brightness of the display panel. The thickness of the part of the third conductive portion beyond the second conductive portion is less than the thickness of the part of the third conductive portion in contact with the second conductive portion and greater than the thickness of the first conductive portion. In the process of etching the first conductive portion, the surface, facing toward the substrate, of the part of the third conductive portion beyond the second conductive portion is etched at the same time. After the first conductive portion is formed, the third conductive portion is still beyond the second conductive portion. In this case, after the first conductive portion is formed by etching, it is not required to etch the second conductive portion to enable the edge of the second conductive portion to be inwardly shrunk relative to the edge of the first conductive portion, simplifying the preparation process of the display substrate. Further, after the first conductive portion is formed by etching, it is not required to etch the second conductive portion. Thus, corrosion of the etching solution for etching the second conductive portion on the conductive structure of the pixel circuit between the sub-pixels and the substrate can be avoided, so as to avoid influence on the electrical connection of the pixel circuit and the first electrode, and further to avoid that the sub-pixels cannot be lighted up, thereby improving the reliability of the display substrate.

### BRIEF DESCRIPTION OF DRAWINGS

FIG. 1 is a partial sectional view illustrating a display substrate according to an example of the present disclosure.

FIG. 2 is a partial sectional view illustrating a display substrate according to an example of the present disclosure.

FIG. 3 is a partial sectional view illustrating an isolation structure of a display substrate according to an example of the present disclosure.

FIG. 4 is a schematic diagram illustrating a partial structure of a display substrate according to an example of the present disclosure.

FIG. 5 is a sectional view illustrating a partial structure of the display substrate shown in FIG. 4.

FIG. 6 is a schematic diagram illustrating a partial structure of a display substrate according to another example of the present disclosure.

FIG. 7 is a sectional view illustrating a partial structure of the display substrate shown in FIG. 6.

FIG. 8 is a flowchart illustrating a manufacturing method for a display substrate according to an example of the present disclosure.

FIG. 9 is a partial sectional view illustrating a first middle structure of a display substrate according to an example of the present disclosure.

FIG. 10 is a partial sectional view illustrating a second middle structure of a display substrate according to an example of the present disclosure.

FIGS. 11 and 12 are partial sectional views illustrating a third middle structure of a display substrate according to an example of the present disclosure.

FIG. 13 is a partial sectional view illustrating a fourth middle structure of a display substrate according to an example of the present disclosure.

FIG. 14 is a partial sectional view illustrating a fifth middle structure of a display substrate according to an example of the present disclosure.

FIG. 15 is a partial sectional view illustrating a sixth middle structure of a display substrate according to an example of the present disclosure.

### DETAILED DESCRIPTION

Examples will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses and methods consistent with some aspects of the present disclosure as detailed in the appended claims.

The terms used in the present disclosure are for the purpose of describing particular examples only, and are not intended to limit the present disclosure. Terms determined by “a”, “the” and “said” in their singular forms in the present disclosure and the appended claims are also intended to include plurality, unless clearly indicated otherwise in the context. It should also be understood that the term “and/or” as used herein refers to and includes any and all possible combinations of one or more of the associated listed items.

It is to be understood that, although the terms such as “first,” “second,” “third,” and the like may be used in the present disclosure to describe various information, such information should not be limited to these terms. These terms are only used to distinguish one category of information from another. For example, without departing from the scope of the present disclosure, first information may be referred as second information; and similarly, the second information may also be referred as the first information. Depending on the context, the term “if” as used herein may be interpreted as “when” or “upon” or “in response to determining”.

One or more embodiments of the present disclosure provide a display substrate and a manufacturing method therefor, and a display apparatus. In combination with the drawings, detailed descriptions will made below to the display substrate and the manufacturing method therefor and the display apparatus in the embodiments of the present disclosure. In case of no conflicts, the features in the following embodiments can be supplemented or combined mutually.

An embodiment of the present disclosure provides a display substrate. The display substrate includes a display region. As shown in FIG. 1, the display substrate includes a substrate 10, a plurality of sub-pixels 20 located on the substrate 10, an auxiliary electrode 30 located on the substrate 10, and an isolation structure 40 located at a side of the auxiliary electrode 30 away from the substrate 10.

The plurality of sub-pixels 20 are located in the display region. The sub-pixel 20 includes a first electrode 21, a light-emitting material layer 22 located at a side of the first electrode 21 away from the substrate 10, and a second electrode 23 located at a side of the light-emitting material layer 22 away from the substrate 10.

As shown in FIGS. 1 to 3, the isolation structure 40 includes a first conductive portion 41, a second conductive portion 42 located at a side of the first conductive portion 41 away from the substrate 10, and a third conductive portion 43 located at a side of the second conductive portion 42 away from the substrate 10. An orthographic projection of the second conductive portion 42 on the substrate 10 falls within an orthographic projection of the third conductive portion 43 on the substrate 10, and an area of the orthographic projection of the second conductive portion 42 is smaller than an area of the orthographic projection of the third conductive portion 43 on the substrate 10. The isolation structure 40 is electrically connected with the auxiliary electrode 30. A thickness of a part of the third conductive portion 43 beyond the second conductive portion 42 is smaller than a thickness of a part of the third conductive portion 43 in contact with the second conductive portion 42. The part of the third conductive portion 43 beyond the second conductive portion 42 refers to a part of the third conductive portion 43 of which an orthographic projection on the substrate has no overlap with the orthographic projection of the second conductive portion 42 on the substrate. The part of the third conductive portion 43 in contact with the second conductive portion 42 refers to a part of the third conductive portion 43 of which the orthographic projection on the substrate overlaps with the orthographic projection of the second conductive portion on the substrate 10. The isolation structure 40 is in contact with the electrode 23.

In the display substrate provided by the embodiments of the present disclosure, since the third conductive portion of the isolation structure goes beyond the second conductive portion, the light-emitting material layer of the sub-pixels can be broken at a sidewall of the isolation structure and hence the second electrode can be in contact with the isolation structure. Since the isolation structure is electrically connected with the auxiliary electrode, the second electrode has a reduced resistance and a reduced voltage drop, reducing a current difference of the sub-pixels of a central region and an edge region of the display panel, and improving a uniformity of a display brightness of the display panel. The thickness of the part of the third conductive portion beyond the second conductive portion is less than the thickness of the part of the third conductive portion in contact with the second conductive portion and greater than the thickness of the first conductive portion, and therefore the third conductive portion and the first conductive portion can be obtained by performing etching in one wet etching process. After the first conductive portion is obtained by etching, it is not required to perform etching on the second conductive portion to enable an edge of the second conductive portion to be inwardly shrunk relative to an edge of the first conductive portion, helping reduce the complexity of the preparation process of the display substrate. Since it is not required to perform etching on the second conductive portion after the first conductive portion is formed by etching, corrosion of an etching solution for etching the second conductive portion on a conductive structure of a pixel circuit between the sub-pixels and the substrate can be avoided, so as to avoid influence on the electrical connection of the pixel circuit and the first electrode, and further to avoid that the sub-pixels cannot be lighted up, thereby improving the reliability of the display substrate.

In some embodiments, the substrate 10 may be a flexible substrate or a rigid substrate. Material of the flexible substrate may include one or more of polyimide, polyethylene terephthalate, polycarbonate and organic resin material. The organic resin material may include epoxy resin, triazine, silicone resin or polyimide or the like. The rigid substrate may include any one of glass substrate, quartz substrate, sapphire substrate and the like. In some embodiments, the display substrate is a transparent display substrate, and the substrate 10 is a substrate with high light transmittance, for example, a glass substrate.

In some embodiments, as shown in FIG. 1, the display substrate further includes a buffer layer 80 located at a side of the substrate 10 away from the substrate 10.

In some embodiments, the display substrate is a transparent display substrate. As shown in FIG. 1, the display region of the display substrate includes a light-emitting region 101 and a light-transmitting region 102. The light-transmitting region 102 is located between adjacent light-emitting regions 101. The sub-pixels 20 are located in the light-emitting region 101. The isolation structure 40 is located in the light-transmitting region 102.

In some embodiments, as shown in FIG. 1, the display substrate further includes a pixel circuit layer 50 between the substrate 10 and the sub-pixels 20; the pixel circuit layer 50 includes a plurality of pixel circuits. The pixel circuits of the pixel circuit layer are in one-to-one correspondence with the sub-pixels 20, that is, each pixel circuit drives one corresponding sub-pixel. The pixel circuit layer includes a plurality of conductive structures. The pixel circuits include a thin film transistor 501. The thin film transistor 501 includes an active layer 511, a gate electrode 512, a first pole 513 and a second pole 514. The first pole 513 is electrically connected with the first electrode 21 of the sub-pixel 20. One of the first pole 513 and the second pole 514 is a source electrode and the other is a drain electrode. The first pole 513 and the second pole 514 are disposed in a same layer. The plurality of conductive structures at least include the gate electrode 512, the first pole 513 and the second pole 514.

In some embodiments, as shown in FIG. 1, the pixel circuit layer 50 further includes a gate insulation layer 51 between the active layer 511 and the gate electrode 512, an interlayer dielectric layer 52 at a side of the gate electrode 512 away from the substrate 10, a passivation layer 53 at a side of the interlayer dielectric layer 52 away from the substrate 10, and a planarization layer 54 at a side of the passivation layer 53 away from the substrate 10. The first pole 513 and the second pole 514 are partially located between the interlayer dielectric layer 52 and the passivation layer 53, and partially located in a through hole penetrating the interlayer dielectric layer 52 and partially in contact with the conducted active layer 511. One of the first pole 513 and the second pole 514 is a source electrode and the other is a drain electrode. The first electrode 21 is electrically connected with the first pole 513 via a through hole penetrating the passivation layer 53 and the planarization layer 54.

In some embodiments, as shown in FIG. 1, a light shielding layer 70 is disposed between the substrate 10 and the pixel circuit layer 50 in the display substrate, and an orthographic projection of the active layer 511 on the substrate 10 falls within an orthographic projection of the light shielding layer 70 on the substrate 10. The light shielding layer 70 can prevent external light from being incident on the active layer 511 and further causing drift of characteristics of the thin film transistor 501 due to illumination on the active layer 511. The light shielding layer 70 may be located between the substrate 10 and the buffer layer 80.

In some embodiments, the material of the light shielding layer 70 is a conductive material, the display substrate further includes a connection portion 515, and the first pole 513 and the connection portion 515 are respectively lap-jointed with the light shielding layer 70 via a through hole penetrating the buffer layer 80 and the interlayer dielectric layer 52. In this way, the first pole 513 is electrically connected with the connection portion 515 through the light shielding layer 70. The first electrode 21 is electrically connected with the connection portion 515 via a through hole penetrating the passivation layer 53 and the planarization layer 54, and thus the first electrode 21 is electrically connected to the first pole 513 sequentially through the connection portion 515 and the light shielding layer 70. The connection portion 515 and the first pole 513 can be disposed in a same layer.

In some embodiments, the display substrate is a transparent display substrate, and there is an overlapping region between an orthographic projection of the light shielding layer 70 on the substrate 10 and an orthographic projection of the first electrode 21 on the substrate 10, for example, the orthographic projection of the light shielding layer 70 on the substrate 10 falls within the orthographic projection of the first electrode 21 on the substrate 10. The first electrode 21 includes a reflection electrode layer. In this way, disposal of the light shielding layer 70 will not further reduce light transmittance of the display substrate.

In some embodiments, one of the first electrode 21 and the second electrode 23 is an anode and the other is a cathode. For example, the first electrode 21 is an anode and the second electrode 23 is a cathode. The display substrate includes an electrode layer which includes the second electrode of each sub-pixel. The electrode layer includes a plurality of electrode blocks 24 each of which includes one or more second electrodes 23 of the sub-pixels. When one electrode block 24 includes more than one second electrode 23 of the sub-pixels, the second electrodes 23 of the sub-pixels 20 are connected to form the electrode block 24. The light-emitting material layer 22 may be an organic light-emitting material layer. The light-emitting material layer 22 is broken at the sidewall of the isolation structure 40. Specifically, the light-emitting material layer 22 may be partially located on top of the isolation structure 40 and partially located at a side of the first conductive portion 41 of the isolation structure 40 away from the substrate 10; and the part on the top of the isolation structure 40 and the part at the side of the first conductive portion 41 away from the substrate are not continuous.

In some embodiments, as shown in FIG. 1, the display substrate further includes a pixel definition layer 60 provided with a plurality of pixel openings, and the plurality of pixel openings are in one-to-one correspondence with the plurality of sub-pixels 20. The pixel definition layer 60 covers an edge region of the first electrodes 21 and the pixel opening exposes the first electrode 21 of the corresponding sub-pixel 20. The light-emitting material layer 22 of the sub-pixel 20 is partially located in the corresponding pixel opening and partially located at a side of the pixel definition layer away from the substrate 10.

In some embodiments, the thickness of the part of the third conductive portion 43 in contact with the second conductive portion 42 is greater than the thickness of the first conductive portion 41. In the process of forming the display substrate, the thicknesses of various portions of the originally-formed third conductive portion 43 are same; then, in the process of forming the first conductive portion 41 by wet etching procedure, the etching solution can simultaneously etch the surfaces, facing toward the substrate 10, of the parts of the third conductive portion 43 beyond the second conductive portion 42 such that the thickness of the part of the third conductive portion 43 in contact with the second conductive portion 42 is greater than the thickness of the part of the third conductive portion 43 beyond the second conductive portion 42. Since the thickness of the part of the third conductive portion in contact with the second conductive portion is greater than the thickness of the first conductive portion, it can be avoided that in the process of forming the first conductive portion 41 by wet etching procedure, the part of the third conductive portion 43 beyond the second conductive portion 42 is almost completely etched off. The thicknesses of various positions of the originally-formed third conductive portion 43 are same, which means that the thicknesses of various positions of the originally-formed third conductive portion are basically same and the thicknesses with a thickness difference within a process error in different regions are also deemed as same.

In some embodiments, a ratio of the thickness of the part of the third conductive portion 43 in contact with the second conductive portion 42 to the thickness of the first conductive portion 41 is in a ratio range of 2 to 5. By setting the ratio of the thickness of the part of the third conductive portion 43 in contact with the second conductive portion 42 to the thickness of the first conductive portion 41 to 2 to 5, a too small thickness ratio of both can be avoided. In the process of forming the first conductive portion 41 by wet etching procedure, the part of the third conductive portion 43 beyond the second conductive portion 42 is almost completely etched off, which can also avoid a too small thickness ratio of both which leads to a lengthened process time required for deposition of a conductive material in the process of forming the third conductive portion 43. In some embodiments, the ratio of the thickness of the part of the third conductive portion 43 in contact with the second conductive portion 42 to the thickness of the first conductive portion 41 may be 2, 3, 4 or 5 or the like.

In some embodiments, the materials of the third conductive portion 43 and the first conductive portion 41 are same. In this case, in the process of forming the first conductive portion 41 by wet etching procedure, an etching speed of the etching solution for a film layer where the first conductive portion 41 is located is identical to an etching speed of the etching solution for a film layer where the third conductive portion 43 is located, which helps ensure the third conductive portion 43 goes beyond the second conductive portion 42 after the first conductive portion 41 is formed by wet etching procedure.

In some embodiments, as shown in FIG. 1, the first electrode 21 includes a fourth conductive portion 211, a fifth conductive portion 212 at a side of the fourth conductive portion 211 away from the substrate 10, and a sixth conductive portion 213 at a side of the fifth conductive portion 212 away from the substrate 10; the fourth conductive portion 211 and the first conductive portion 41 are disposed in a same layer, the fifth conductive portion 212 and the second conductive portion 42 are disposed in a same layer, and the sixth conductive portion 213 and the third conductive portion 43 are disposed in a same layer. It should be noted that the term “A and B are disposed in a same layer” means that A and B are located on a surface of a same film layer and both in direct contact with the surface. In some embodiments, A and B are formed by performing one-time patterning process on a same film layer. In some embodiments, A and B are located on a surface of a same film layer and both in direct contact with the surface, and A and B both have substantially same height or thickness. The fourth conductive portion 211 and the first conductive portion 41 can be formed by performing one-time patterning process on a same film layer: the fifth conductive portion 212 and the second conductive portion 42 can be formed by performing one-time patterning process on a same film layer: the sixth conductive portion 213 and the third conductive portion 43 can be formed by performing one-time patterning process on a same film layer. In this way, the preparation process of the display substrate can be simplified.

In some embodiments, as shown in FIG. 1, the first electrode 21 further includes a seventh conductive portion 214 at a side of the fourth conductive portion 211 facing toward the substrate 10; the isolation structure 40 further includes an eighth conductive portion 44 at a side of the first conductive portion 41 facing toward the substrate 10; the seventh conductive portion 214 and the eighth conductive portion 44 are disposed in a same layer. Therefore, the seventh conductive portion 214 and the eighth conductive portion 44 can be formed by performing one-time patterning process on a same film layer, helping simplify the preparation process of the display substrate. In the preparation process of the display substrate, the eighth conductive portion is firstly formed, and then a first conductive layer, a second conductive layer and a third conductive layer are formed sequentially on the eighth conductive portion, where orthographic projections of the first conductive layer, the second conductive layer and the third conductive layer on the substrate all cover the substrate; then, the first conductive layer, the second conductive layer and the third conductive layer are etched to form the first conductive portion, the second conductive portion and the third conductive portion. Since the second conductive layer is formed at a side of the first conductive layer away from the substrate, the second conductive layer is prevented from directly contacting with the planarization layer which results mismatching in stress with planarization layer and bulges on the second conductive layer, thereby avoiding affecting the quality of the subsequently-formed second conductive portion and sixth conductive portion.

In some embodiments, material of at least one conductive portion of the fourth conductive potion 211, the fifth conductive portion 212, the sixth conductive portion 213 and the seventh conductive portion 214 is a reflective conductive material. For example, the materials of the fourth conductive portion 211, the fifth conducive portion 212 and the seventh conductive portion 214 may be transparent conductive materials, and the material of the sixth conductive portion 213 is a reflective conductive material. The materials of the fourth conductive portion 211, the fifth conducive portion 212 and the seventh conductive portion 214 may include at least one of indium zinc oxide, indium tin oxide and the like, and the material of the sixth conductive portion 213 may include copper, silver and aluminium alloy and the like.

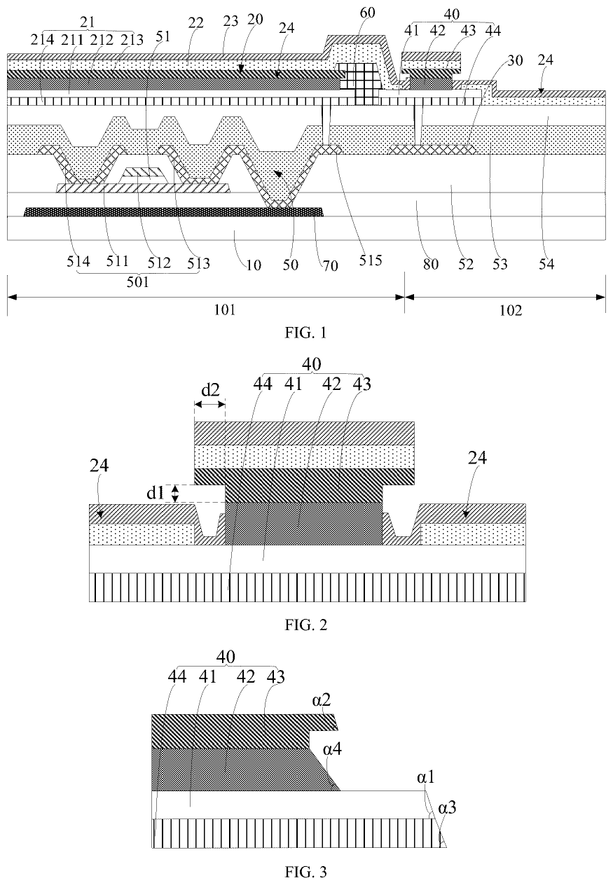

In some embodiments, as shown in FIGS. 2 and 3, the orthographic projection of the third conductive portion 43 on the substrate 10 falls within the orthographic projection of the first conductive portion 41 on the substrate 10. The light-emitting material layer 22 is broken at the sidewall of the isolation structure 40, and adjacent electrode blocks 24 are lap-jointed with a same isolation structure 40 respectively. Setting the orthographic projection of the third conductive portion 43 on the substrate 10 to fall within the orthographic projection of the first conductive portion 41 on the substrate 10 further helps the electrode block 24 to lap-joint with the first conductive portion 41. Since adjacent electrode blocks 24 are lap-jointed by the first conductive portion 41 of the isolation structure, the electrode blocks 24 of the electrode layer are finally electrically connected together. The electrode blocks 24 may share one same power line, helping simplify the lines of the display substrate. That the orthographic projection of the third conductive portion 43 on the substrate 10 falls within the orthographic projection of the first conductive portion 41 on the substrate 10 refers to the area of the orthographic projection of the third conductive portion 43 on the substrate 10 is equal to the area of the orthographic projection of the first conductive portion 41 on the substrate 10 or the area of the orthographic projection of the third conductive portion 43 on the substrate 10 is less than the area of the orthographic projection of the first conductive portion 41 on the substrate 10. FIG. 3 is a schematic diagram illustrating a middle structure in a preparation process, and a mask layer 94 is formed on the top of the third conductive portion 43 in FIG. 3.

In some embodiments, the thickness of the part of the third conductive portion 43 in contact with the second conductive portion 42 is a first thickness, and the thickness of the part of the third conductive portion 43 beyond the second conductive portion 42 is a second thickness. As shown in FIG. 2, a difference between the first thickness and the second thickness is d1, a length of the third conductive portion 43 beyond the second conductive portion 42 is d2, and a ratio of d2 to d1 ranges from 10 to 40. In this way, it can be avoided that the ratio of d2 to d1 is too small which results that the length of the third conductive portion 43 beyond the second conductive portion 42 is too small and thus the light-emitting material layer 22 cannot be effectively blocked: it can also be avoided that the ratio of d2 to d1 is too large which results that the thickness of the part of the third conductive portion 43 beyond the second conductive portion 42 is too small, and the part of the third conductive portion 43 beyond the second conductive portion 42 easily collapses. In some embodiments, the ratio of d2 to d1 may be 10, 15, 20, 25, 30, 35, or 40 or the like. For example, the d2 may be 0.2 μm to 2 μm: and the d1 may be 200 Å to 500 Å.

In some embodiments, the ratio of the second thickness to the first thickness ranges from 1/3 to 1/2.

In an example, the length of the part of the third conductive portion 43 beyond the second conductive portion 42 is about 0.4 um, the thickness of the eighth conductive portion 44 is about 1400 Å, the thickness of the first conductive portion 41 is about 300 Å, the thickness of the second conductive portion 42 is about 6000 Å, the thickness of the part of the third conductive portion 43 in contact with the second conductive portion 42 is about 920 Å, and the thickness of the part of the third conductive portion 43 beyond the second conductive portion 42 is about 500 Å.

In some embodiments, the first conductive portion 41, the second conductive portion 42, the third conductive portion 43, and the eighth conductive portion 44 are all obtained by wet etching procedure. As shown in FIG. 3, included angles between side surfaces of the first conductive portion 41, the third conductive portion 43 and the eighth conductive portion 44 and the surface of the substrate 10 are α1, α2 and α3 respectively, where the α1, α2 and α3 are all between 70° and 90°. A side surface of the second conductive portion is an inclined surface and an included angle between the inclined surface and the surface of the substrate is α4, where α4 is between 30° and 80°.

In some embodiments, the auxiliary electrode 30 is disposed in the same layer as at least one conductive structure of the pixel circuit layer 50. In this way, the auxiliary electrode 30 and the conductive structure of the pixel circuit layer 50 can be formed by performing one-time patterning process on a same film layer, helping simplify the preparation process of the display substrate. In the embodiment shown in FIG. 1, the auxiliary electrode 30 is disposed in the same layer as the first pole 513 and the second pole 514 of the pixel circuit layer 50. In other embodiments, the auxiliary electrode 30 may be disposed in the same layer as the gate electrode 512 of the pixel circuit layer 50.

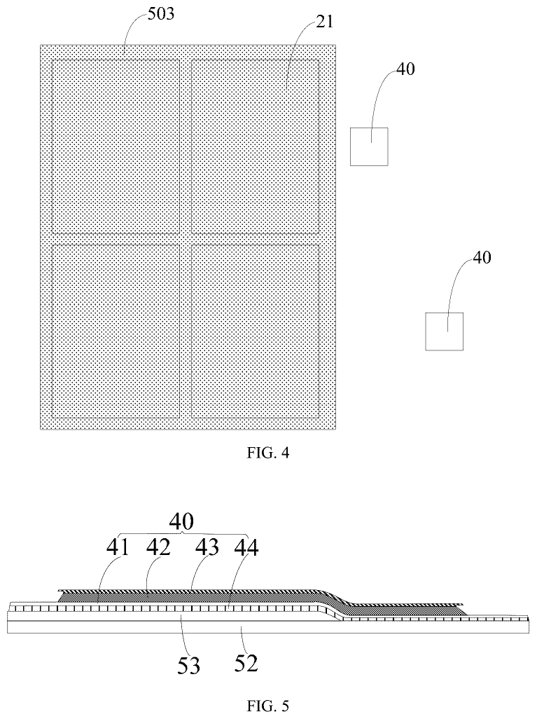

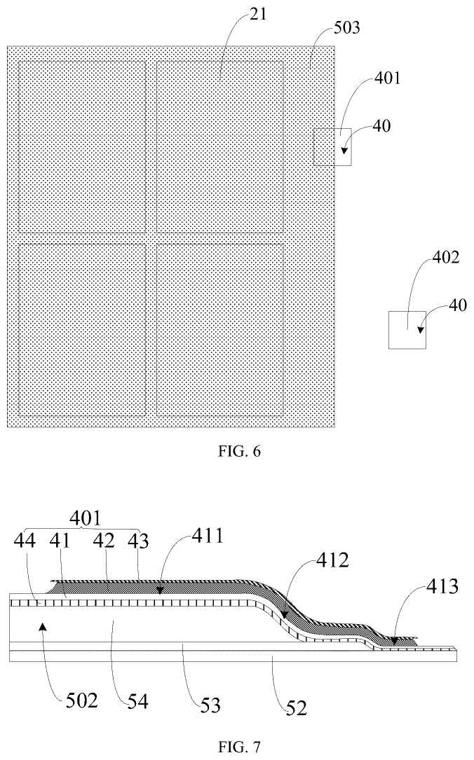

In some embodiments, as shown in FIG. 4, the orthographic projection of the isolation structure 40 on the substrate 10 is not overlapped with the orthographic projection of at least one organic layer 503 on the substrate 10. In some embodiments, the organic layer of the pixel circuit layer 50 may include the planarization layer 54. As shown in FIG. 5, the isolation structure 40 is in direct contact with the passivation layer 53, and the orthographic projection of the isolation structure 40 on the substrate 10 is not overlapped with the orthographic projection of the planarization layer on the substrate 10. In the embodiment shown in FIG. 5, the orthographic projection of the isolation structure 40 on the substrate is partially overlapped with the orthographic projection of the passivation layer 53 on the substrate, and the isolation structure 40 is partially in contact with the passivation layer 53 and partially in contact with the interlayer dielectric layer 52. In some other embodiments, as shown in FIG. 6, the isolation structure 40 includes a first-class isolation structure 401 and a second-class isolation structure 402, and a distance of the first-class isolation structure 401 from the first electrode 21 is less than a distance of the second-class isolation structure 402 from the first electrode 21; the orthographic projection of the first-class isolation structure 401 on the substrate 10 is overlapped with the orthographic projection of at least one organic layer 503 on the substrate 10, and the orthographic projection of the second-class isolation structure 402 on the substrate 10 is not overlapped with the orthographic projection of at least one organic layer 503 on the substrate 10.

Furthermore, as shown in FIG. 7, the at least one organic layer includes an organic material layer 502, and the first-class isolation structure 401 includes a first portion 411, a second portion 412 and a third portion 413 sequentially connected. The first portion 411 is located at a side of the organic material layer 502 away from the substrate 10, the second portion 412 is located at a side part of the organic material layer, and the orthographic projection of the third portion 413 on the substrate 10 is not overlapped with the orthographic projection of the organic material layer 502 on the substrate 10. In the embodiment shown in FIG. 7, the organic material layer 502 is the planarization layer 54, and the third portion 413 of the first-class isolation structure 401 is in direct contact with the passivation layer 53.

In some embodiments, the first-class isolation structure 401 is partially in the light-emitting region and partially in the light-transmitting region; the third conductive portion 43 goes beyond the second conductive portion 42 in the part of the first-class isolation structure 401 in the light-emitting region, and the third conductive portion 43 may go beyond the second conductive portion 42 or not go beyond the second conductive portion 42 in the part of the first-class isolation structure 401 in the light-transmitting region. In the embodiment shown in FIG. 7, the third portion 413 of the first-class isolation structure 401 is located in the light-transmitting region, and in the third portion 413, the third conductive portion 43 goes beyond the second conductive portion 42.

In some embodiments, the display substrate further includes an encapsulation layer at a side of the second electrode away from the substrate, and an orthographic projection of the encapsulation layer on the substrate may cover the substrate. The encapsulation layer may be a thin film encapsulation layer including an inorganic layer and an organic layer arranged alternately, and the film layer most distant from the substrate is the inorganic layer.

An embodiment of the present disclosure further provides a manufacturing method for a display substrate. As shown in FIG. 1, the display substrate includes a plurality of sub-pixels in a display region, and the sub-pixel includes a first electrode, a second electrode and a light-emitting material layer between the first electrode and the second electrode.

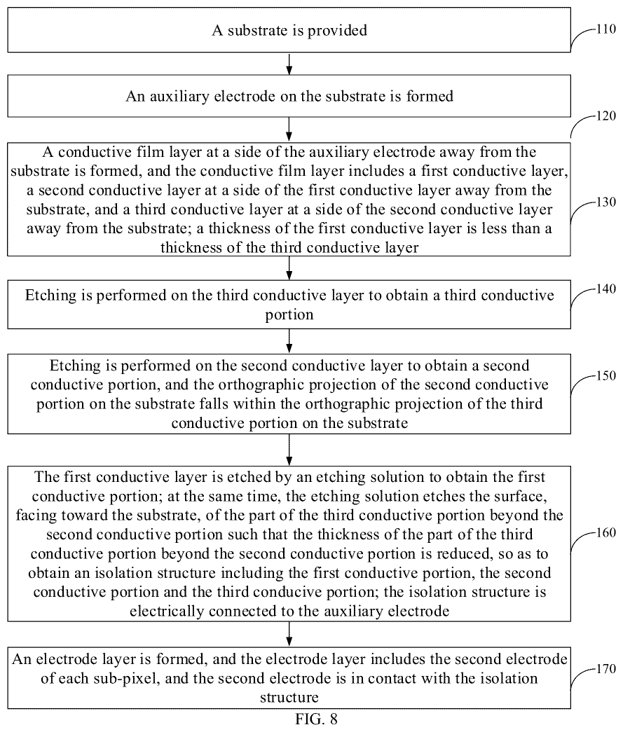

As shown in FIG. 8, the manufacturing method includes steps 110 to 170. The steps will be detailed below.

At step 110, a substrate is provided.

The second electrode of the sub-pixel is located at a side of the first electrode away from the substrate.

At step 120, an auxiliary electrode on the substrate is formed.

In some embodiments, the manufacturing method of the display substrate further includes: forming a pixel circuit layer on the substrate.

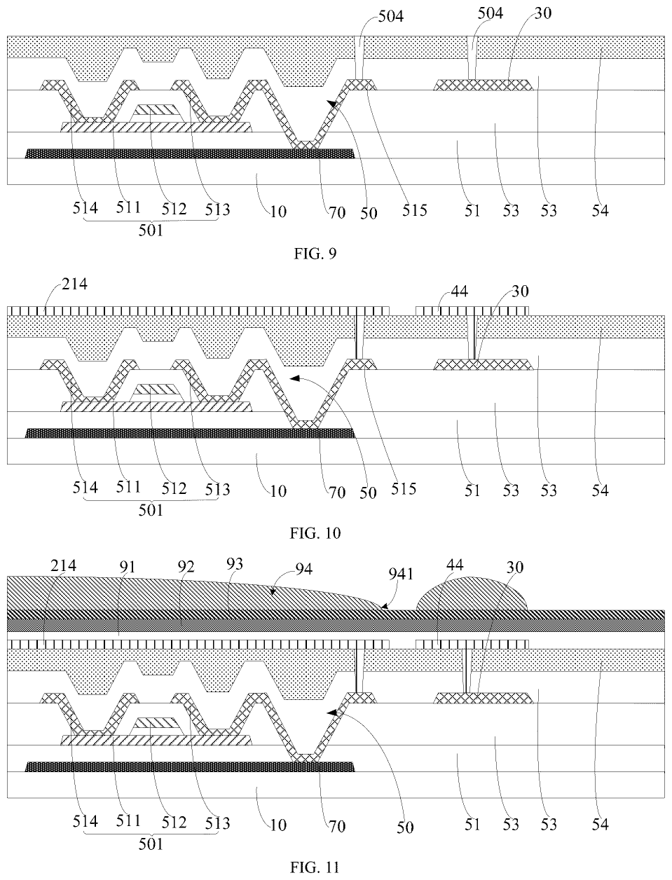

In some embodiments, before forming the pixel circuit layer on the substrate, the manufacturing method of the display substrate further includes: forming a light shielding layer on the substrate. The pixel circuit layer is formed at a side of the light shielding layer away from the substrate. After the light shielding layer, the auxiliary electrode and the pixel circuit layer are formed, a first middle structure shown in FIG. 9 can be obtained.

In some embodiments, the pixel circuit layer includes a plurality of conductive structures, and the auxiliary electrode and at least one conductive structure are disposed in a same layer.

In some embodiments, as shown in FIG. 9, the pixel circuit layer 50 includes a thin film transistor 501 and a connection portion 515; the thin film transistor 501 includes a first pole 513 and a second pole 514; and the auxiliary electrode 30, the connection portion 515, the first pole 513 and the second pole 514 are disposed in a same layer. The step of forming the pixel circuit layer on the substrate may include the following process. It is noted that the “thin film” below refers to one layer of thin film prepared by carrying out deposition or coating process for a material on the substrate and an orthographic projection of the “thin film” on the substrate covers the substrate.

Firstly, an active layer thin film is deposited on the substrate 10, and patterning is performed on the active layer thin film by patterning process to form an active layer 511.

Next, a gate insulation thin film is deposited and patterning is performed on the gate insulation thin film by patterning process to form a gate insulation layer 51.

Next, a first metal thin film is deposited, and patterning is performed on the first metal thin film by patterning process to form a gate electrode 512.

Next, an interlayer dielectric layer 52 is deposited; a plurality of first through holes penetrating the interlayer dielectric layer 52 on the interlayer dielectric layer 52 and a second through hole penetrating the interlayer dielectric layer 52 and a buffer layer 80 are formed; one active layer 511 corresponds to two first through holes exposing a part of the corresponding active layer 511, and the second through hole exposes a part of the light shielding layer 70.

Next, a second metal thin film is deposited and patterning is performed on the second metal thin film by patterning process to form the first pole 513, the second pole 514, the auxiliary electrode 30 and the connection portion 515; the first pole 513 and the second pole 514 are in contact with the active layer 511 via one through hole respectively, and the first pole 513 and the connection portion 515 are electrically connected to the light shielding layer 70 via the second through hole respectively.

Next, a passivation layer 53 and a planarization layer 54 are deposited sequentially, and third through holes 504 penetrating the passivation layer 53 and the planarization layer 54 are formed; a partial region of the connection portion 515 is exposed by one third through hole 504 and a partial region of the auxiliary electrode 30 is exposed by another third through hole 504.

At step 130, a conductive film layer at a side of the auxiliary electrode away from the substrate is formed, and the conductive film layer includes a first conductive layer, a second conductive layer at a side of the first conductive layer away from the substrate, and a third conductive layer at a side of the second conductive layer away from the substrate; a thickness of the first conductive layer is less than a thickness of the third conductive layer.

In some embodiments, the first electrode includes a seventh conductive portion and the isolation structure includes an eighth conductive portion. Before the step 130, the manufacturing method for the display substrate further includes the following steps.

Firstly, a fourth conductive layer is formed, and an orthographic projection of the fourth conductive layer on the substrate covers the substrate.

Next, patterning treatment is performed on the fourth conductive layer to obtain the seventh conductive portion and the eighth conductive portion.

By the above steps, a second middle structure shown in FIG. 10 can be obtained. As shown in FIG. 10, the seventh conductive portion 214 and the eighth conductive portion 44 are located on the pixel circuit layer 50; the seventh conductive portion 214 is electrically connected to the connection portion 515 via a third through hole, and the eighth conductive portion 44 is electrically connected to the auxiliary electrode 30 via a third through hole.

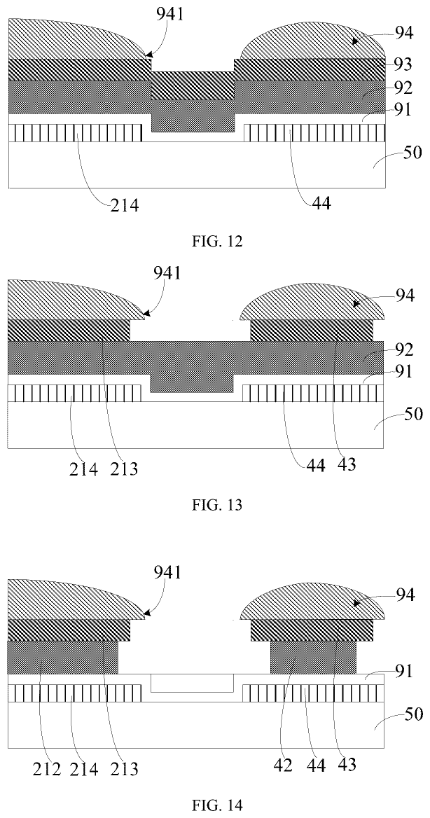

After the step 130, a mask layer is disposed at a side of the third conductive layer away from the substrate. The mask layer can be obtained by performing exposure development on photoresist. After the mask layer is formed, a third middle structure shown in FIGS. 11 and 12 can be obtained. As shown in FIGS. 11 and 12, the orthographic projections of the first conductive layer 91, the second conductive layer 92 and the third conductive layer 93 on the substrate 10 all cover the substrate 10. An opening 941 is opened on the mask layer 94 and etching can be performed on the first conductive layer 91, the second conductive layer 92 and the third conductive layer 93 through the opening 941.

The orthographic projection of the first conductive layer 91 on the substrate 10 covers the substrate 10, namely, the first conductive layer 91 covers the seventh conductive portion 214, the eighth conductive portion 414 and the exposed planarization layer 54. The second conductive layer 92 is formed at a side of the first conductive layer 91 away from the substrate 10, which prevents the second conductive layer 92 from directly contacting with the planarization layer 54 which results mismatching in stress with planarization layer 54 and bulges on the second conductive layer, thereby avoiding affecting the quality of the subsequently-formed second conductive portion and sixth conductive portion.

At step 140, etching is performed on the third conductive layer to obtain a third conductive portion.

In this step, etching can be performed on the third conductive layer by wet etching procedure.

In this step, the sixth conductive portion of the first electrode is obtained while the first conductive portion is obtained.

By this step, a fourth middle structure shown in FIG. 13 can be obtained. As shown in FIG. 13, the third conductive portion 43 and the sixth conductive portion 213 both can be inwardly shrunk relative to the mask layer 94; the orthographic projection of the third conductive portion 43 on the substrate falls within the orthographic projection of the eighth conductive portion 44 on the substrate. Furthermore, an area of the orthographic projection of the third conductive portion 43 on the substrate less than an area of the orthographic projection of the eighth conductive portion 44 on the substrate.

At step 150, etching is performed on the second conductive layer to obtain a second conductive portion, and the orthographic projection of the second conductive portion on the substrate falls within the orthographic projection of the third conductive portion on the substrate.

In this step, the fifth conductive portion of the first electrode is obtained while the second conductive portion is obtained.

By this step, a fifth middle structure shown in FIG. 14 can be obtained. As shown in FIG. 14, the second conductive portion 42 is inwardly shrunk relative to the third conductive portion 43.

At step 160, the first conductive layer is etched by an etching solution to obtain the first conductive portion; at the same time, the etching solution etches the surface, facing toward the substrate, of the part of the third conductive portion beyond the second conductive portion such that the thickness of the part of the third conductive portion beyond the second conductive portion is reduced, so as to obtain an isolation structure including the first conductive portion, the second conductive portion and the third conducive portion; the isolation structure is electrically connected to the auxiliary electrode.

In this step, a fourth conductive portion of the first electrode is obtained while the first conductive portion is obtained.

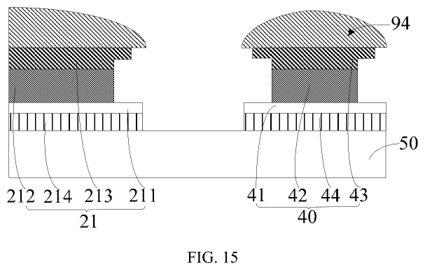

By this step, a sixth middle structure shown in FIG. 15 can be obtained. As shown in FIG. 15, the first electrode 21 includes the seventh conductive portion 214, the fourth conductive portion 211, the fifth conductive portion 212 and the sixth conductive portion 213 sequentially laminated along a direction away from the pixel circuit layer 50; the orthographic projection of the fourth conductive portion 211 on the substrate may be substantially overlapped with the orthographic projection of the seventh conductive portion 214 on the substrate. The isolation structure 40 includes the eighth conductive portion 44, the first conductive portion 41, the second conductive portion 42 and the third conductive portion 43 laminated sequentially along a direction away from the pixel circuit layer 50; the orthographic projection of the first conductive portion 41 on the substrate may be substantially overlapped with the orthographic projection of the eighth conductive portion 44 on the substrate. The thickness of the part of the third conductive portion 43 beyond the second conductive portion 42 is less than the thickness of the part of the third conductive portion 43 in contact with the second conductive portion 42. The orthographic projection of the third conductive portion 43 on the substrate falls within the orthographic projection of the first conductive portion 41 on the substrate. Furthermore, the area of the orthographic projection of the third conductive portion 43 on the substrate is less than the area of the orthographic projection of the first conductive portion 41 on the substrate.

In some embodiments, the material of the first conductive layer 91 is identical to the material of the third conductive layer 93. In this way, when the first conductive layer 91 is etched using the etching solution, the etching speed of the etching solution for the first conductive layer 91 is identical to the etching speed of the etching solution for the surface, facing toward the substrate, of the part of the third conductive portion 43 beyond the second conductive portion 42. Since the thickness of the third conductive portion is identical to the thickness of the third conductive layer 93, the thickness of the first conductive layer 91 is less than the thickness of the third conductive portion 43. After the first conductive layer 91 is etched to form the first conductive portion 41, the part of the third conductive portion 43 beyond the second conductive portion 42 is only partially etched off in thickness direction and thus it can be still ensured that the third conductive portion 43 goes beyond the second conductive portion 42.

In some embodiments, a ratio of the thickness of the third conductive layer to the thickness of the first conductive layer ranges from 2 to 5.

At step 170, an electrode layer is formed, and the electrode layer includes the second electrode of each sub-pixel, and the second electrode is in contact with the isolation structure.

In some embodiments, before the step 170, the manufacturing method for the display substrate further includes: forming a pixel definition layer, where the pixel definition layer is provided with plural pixel openings.

In some embodiments, before the step 170 and after the formation of the pixel definition layer, the manufacturing method for the display substrate further includes: forming a light-emitting material layer, where the light-emitting material layer is partially located in the pixel openings.

By step 170, a display substrate shown in FIG. 1 can be obtained. As shown in FIG. 1, the pixel definition layer 60 covers an edge region of the first electrode 21; the light-emitting material layer 22 is partially located in the pixel openings of the pixel definition layer 60; the light-emitting material layer 22 and the electrode layer are broken at the side wall of the isolation structure 40, and the electrode layer is divided by the isolation structure 40 into several electrode blocks 24, and adjacent electrode blocks 24 are respectively lap-jointed with the first conductive portion 41 of the same isolation structure 40.

In the manufacturing method of the display substrate according to the embodiments of the present disclosure, before the first conductive layer is etched to form the first conductive portion, the third conductive portion goes beyond the second conductive portion; since the thickness of the first conductive layer is less than the thickness of the third conductive portion, when, in the process of etching on the first conductive layer to form the first conductive portion, the surface, facing toward the substrate, of the part of the third conductive portion beyond the second conductive portion is etched, after the first conductive portion is formed, the third conductive portion is still beyond the second conductive portion. In this case, after the first conductive portion is formed by etching, it is not required to etch the second conductive portion to enable the second conductive portion to be inwardly shrunk relative to the first conductive portion, simplifying the preparation process of the display substrate. Further, corrosion of the etching solution for etching the second conductive portion on the conductive structure of the pixel circuit between the sub-pixels and the substrate can be avoided, so as to avoid influence on the electrical connection of the pixel circuit and the first electrode, thereby ensuring the sub-pixels can be lighted up and improving the reliability of the display substrate.

In some embodiments, the display substrate is a transparent display substrate. As shown in FIG. 1, the display region includes a light-emitting region 101 and a light-transmitting region 102 between adjacent light-emitting regions 101; the sub-pixels 20 are located in the light-emitting regions; the isolation structure 40 is located in the light-transmitting region 102. The pixel circuit layer includes at least one organic layer.

In some embodiments, the orthographic projection of the isolation structure on the substrate is not overlapped with the orthographic projection of at least one organic layer on the substrate.

In another embodiment, the isolation structure includes a first-class isolation structure and a second-class isolation structure, and a distance of the first-class isolation structure from the first electrode is less than a distance of the second-class isolation structure from the first electrode; the orthographic projection of the first-class isolation structure on the substrate is overlapped with the orthographic projection of at least one organic layer on the substrate, and the orthographic projection of the second-class isolation structure on the substrate is not overlapped with the orthographic projection of at least one organic layer on the substrate.

In the present disclosure, the embodiments of the display substrate and the embodiments of the manufacturing method of the display substrate are based on the same invention idea, and reference can be made to each other for related details and beneficial effects and thus no redundant descriptions are made herein.

An embodiment of the present disclosure provides a display apparatus, which includes the display substrate in any one of the above embodiments.

In some embodiments, the display apparatus further includes a housing in which the display substrate is embedded.

The display apparatus provided by the embodiments of the present disclosure may be any proper display apparatus, which includes but not limited to smart phone, tablet computer, television, display, laptop computer, digital photo frame, navigator, and electronic book and any other product or component having display function.

It should be noted that in the accompanying drawings, for illustration clarity, the sizes of the layers and regions may be exaggerated. Furthermore, it may be understood that when an element or layer is referred to as being “on” another element or layer, such element or layer may be directly on the another element or layer or there is an intermediate layer therebetween. Further, it is understood that when an element or layer is referred to as being “under” another element or layer, such element or layer may be directly under the another element or layer, or one or more intermediate elements or layers are present therebetween. In addition, it may also be understood that when a layer or element is referred to as being between two layers or elements, such layer or element may be a sole layer between the two layers or elements, or one or more intermediate layers or elements are present. Like reference signs throughout the descriptions indicate like elements.

Other implementations of the present disclosure will be apparent to those skilled in the art from consideration of the specification and practice of the present disclosure herein. The present disclosure is intended to cover any variations, uses, modification or adaptations of the present disclosure that follow the general principles thereof and include common knowledge or conventional technical means in the related art that are not disclosed in the present disclosure. The specification and examples are considered as exemplary only, with a true scope and spirit of the present disclosure being indicated by the following claims.

It is to be understood that the present disclosure is not limited to the precise structure described above and shown in the accompanying drawings, and that various modifications and changes may be made without departing from the scope thereof. The scope of the present disclosure is limited only by the appended claims.

1. A display substrate, comprising:
a substrate;
a plurality of sub-pixels located at a side of the substrate, wherein the plurality of sub-pixels are located in a display region; the sub-pixel comprises a first electrode, a light-emitting material layer at a side of the first electrode away from the substrate, and a second electrode at a side of the light-emitting material layer away from the substrate;
an auxiliary electrode located at a side of the substrate; and
an isolation structure at a side of the auxiliary electrode away from the substrate;
wherein the isolation structure comprises a first conductive portion, a second conductive portion at a side of the first conductive portion away from the substrate, and a third conductive portion at a side of the second conductive portion away from the substrate; an orthographic projection of the second conductive portion on the substrate falls within an orthographic projection of the third conductive portion on the substrate, and an area of the orthographic projection of the second conductive portion on the substrate is less than an area of the orthographic projection of the third conductive portion on the substrate; the isolation structure is electrically connected with the auxiliary electrode; a thickness of a part of the third conductive portion beyond the second conductive portion is less than a thickness of a part of the third conductive portion in contact with the second conductive portion; the isolation structure is electrically connected with the second electrode.

2. The display substrate of claim 1, wherein the thickness of the part of the third conductive portion in contact with the second conductive portion is greater than a thickness of the first conductive portion.

3. The display substrate of claim 2, wherein a ratio of the thickness of the part of the third conductive portion in contact with the second conductive portion to the thickness of the first conductive portion ranges from 2 to 5.

4. The display substrate of claim 1, wherein the orthographic projection of the third conductive portion on the substrate falls within an orthographic projection of the first conductive portion on the substrate; the display substrate comprises an electrode layer, and the electrode layer comprises the second electrode of each sub-pixel; the electrode layer comprises a plurality of electrode blocks, and each of the electrode blocks comprises the second electrodes of one or more sub-pixels; adjacent electrode blocks are respectively lap-jointed with the same isolation structure.

5. The display substrate of claim 1, wherein the first electrode comprises a fourth conductive portion, a fifth conductive portion at a side of the fourth conductive portion away from the substrate, and a sixth conductive portion at a side of the fifth conductive portion away from the substrate; the fourth conductive portion and the first conductive portion are disposed in a same layer, the fifth conductive portion and the second conductive portion are disposed in a same layer, and the sixth conductive portion and the third conductive portion are disposed in a same layer.

6. The display substrate of claim 5, wherein the first electrode further comprises a seventh conductive portion at a side of the fourth conductive portion facing toward the substrate, and the isolation structure further comprises an eighth conductive portion at a side of the first conductive portion facing toward the substrate; the seventh conductive portion and the eighth conductive portion are disposed in a same layer.

7. The display substrate of claim 1, wherein the display substrate further comprises a pixel circuit layer between the substrate and the sub-pixels; the pixel circuit layer comprises a plurality of conductive structures; the auxiliary electrode and at least one of the conductive structures are disposed in a same layer.

8. The display substrate of claim 1, wherein the display region comprises a light-emitting region and a light-transmitting region between adjacent light-emitting regions; the sub-pixels are located in the light-emitting region; the isolation structure is located in the light-transmitting region; the display substrate further comprises a pixel circuit layer between the substrate and the sub-pixels, and the pixel circuit layer comprises at least one organic layer; and
an orthographic projection of the isolation structure on the substrate is not overlapped with an orthographic projection of the at least one organic layer on the substrate.

9. The display substrate of claim 1, wherein the display region comprises a light-emitting region and a light-transmitting region between adjacent light-emitting regions; the sub-pixels are located in the light-emitting region; the isolation structure is located in the light-transmitting region; the display substrate further comprises a pixel circuit layer between the substrate and the sub-pixels, and the pixel circuit layer comprises at least one organic layer; and
the isolation structure comprises a first-class isolation structure and a second-class isolation structure, and a distance of the first-class isolation structure from the first electrode is less than a distance of the second-class isolation structure from the first electrode; an orthographic projection of the first-class isolation structure on the substrate is overlapped with an orthographic projection of the at least one organic layer on the substrate, and an orthographic projection of the second-class isolation structure on the substrate is not overlapped with the orthographic projection of the at least one organic layer on the substrate.

10. The display substrate of claim 9, wherein the at least one organic layer comprises an organic material layer, and the first-class isolation structure comprises a first portion, a second portion and a third portion sequentially connected; the first portion is located at a side of the organic material layer away from the substrate, the second portion is located at a side part of the organic material layer, and an orthographic projection of the third portion on the substrate is not overlapped with an orthographic projection of the organic material layer on the substrate.

11. The display substrate of claim 1, wherein the first conductive portion has the same material as the third conductive portion.

12. The display substrate of claim 1, wherein a thickness difference between the part of the third conductive portion in contact with the second conductive portion and the part of the third conductive portion beyond the second conductive portion is d1, a length of the third conductive portion beyond the second conductive portion is d2, and a ratio of d2 to d1 ranges from 10 to 40.

13. The display substrate of claim 1, wherein a side surface of the second conductive portion is an inclined surface and an included angle between the inclined surface and a surface of the substrate ranges from 30° to 80°.

14. A manufacturing method of a display substrate, wherein the display substrate comprises a plurality of sub-pixels in a display region, the sub-pixel comprises a first electrode, a second electrode, and a light-emitting material layer between the first electrode and the second electrode; the manufacturing method comprises:
providing a substrate, wherein the second electrode is located at a side of the first electrode away from the substrate;
forming an auxiliary electrode on the substrate;
forming a conductive film layer at a side of the auxiliary electrode away from the substrate, wherein the conductive film layer comprises a first conductive layer, a second conductive layer at a side of the first conductive layer away from the substrate, and a third conductive layer at a side of the second conductive layer away from the substrate; a thickness of the first conductive layer is less than a thickness of the third conductive layer;
etching the third conductive layer to obtain a third conductive portion;
etching the second conductive layer to obtain a second conductive portion, wherein an orthographic projection of the second conductive portion on the substrate falls within an orthographic projection of the third conductive portion on the substrate, and an area of the orthographic projection of the second conductive portion on the substrate is less than an area of the orthographic projection of the third conductive portion on the substrate;
etching the first conductive layer by using an etching solution to obtain a first conductive portion; wherein at the same time, the etching solution etches a surface, facing toward the substrate, of the part of the third conductive portion beyond the second conductive portion such that the thickness of the part of the third conductive portion beyond the second conductive portion is reduced so as to obtain an isolation structure comprising the first conductive portion, the second conductive portion and the third conductive portion; the isolation structure is electrically connected with the auxiliary electrode; and
forming the second electrode, wherein the second electrode is in contact with the isolation structure.

15. A display apparatus, comprising a display substrate, comprising:
a substrate;
a plurality of sub-pixels located at a side of the substrate, wherein the plurality of sub-pixels are located in a display region; the sub-pixel comprises a first electrode, a light-emitting material layer at a side of the first electrode away from the substrate, and a second electrode at a side of the light-emitting material layer away from the substrate;
an auxiliary electrode located at a side of the substrate; and
an isolation structure at a side of the auxiliary electrode away from the substrate; wherein the isolation structure comprises a first conductive portion, a second conductive portion at a side of the first conductive portion away from the substrate, and a third conductive portion at a side of the second conductive portion away from the substrate; an orthographic projection of the second conductive portion on the substrate falls within an orthographic projection of the third conductive portion on the substrate, and an area of the orthographic projection of the second conductive portion on the substrate is less than an area of the orthographic projection of the third conductive portion on the substrate; the isolation structure is electrically connected with the auxiliary electrode; a thickness of a part of the third conductive portion beyond the second conductive portion is less than a thickness of a part of the third conductive portion in contact with the second conductive portion; the isolation structure is electrically connected with the second electrode.

16. The manufacturing method of claim 14, wherein the thickness of the part of the third conductive portion in contact with the second conductive portion is greater than a thickness of the first conductive portion.

17. The manufacturing method of claim 16, wherein a ratio of the thickness of the part of the third conductive portion in contact with the second conductive portion to the thickness of the first conductive portion ranges from 2 to 5.

18. The manufacturing method of claim 14, wherein the orthographic projection of the third conductive portion on the substrate falls within an orthographic projection of the first conductive portion on the substrate; the display substrate comprises an electrode layer, and the electrode layer comprises the second electrode of each sub-pixel; the electrode layer comprises a plurality of electrode blocks, and each of the electrode blocks comprises the second electrodes of one or more sub-pixels; adjacent electrode blocks are respectively lap-jointed with the same isolation structure.

19. The manufacturing method of claim 14, wherein the first electrode comprises a fourth conductive portion, a fifth conductive portion at a side of the fourth conductive portion away from the substrate, and a sixth conductive portion at a side of the fifth conductive portion away from the substrate; the fourth conductive portion and the first conductive portion are disposed in a same layer, the fifth conductive portion and the second conductive portion are disposed in a same layer, and the sixth conductive portion and the third conductive portion are disposed in a same layer.

20. The manufacturing method of claim 19, wherein the first electrode further comprises a seventh conductive portion at a side of the fourth conductive portion facing toward the substrate, and the isolation structure further comprises an eighth conductive portion at a side of the first conductive portion facing toward the substrate; the seventh conductive portion and the eighth conductive portion are disposed in a same layer.
